(19) United States
(12) Patent Application Publication
(10) Pub. No.: US 2006/0126316 A1
(43) Pub. Date: Jun. 15, 2006

(54) Control circuit board and circuit structural body

(75) Inventors: Kouichi Takagi, Nagoya-shi (JP); Fumiaki Mizuno, Nagoya-shi (JP)

Correspondence Address: OLIFF & BERRIDGE, PLC, P.O. BOX 19928, ALEXANDRIA, VA, 22320, US

(73) Assignees: Autonetworks Technologies, Ltd., Nagoya-shi (JP); Sumitomo Wiring Systems, Ltd., Yokkaichi-shi (JP); Sumitomo Electric Industries, Ltd., Osaka-shi (JP)

(21) Appl. No.: 11/344,251

(22) Filed: Feb. 1, 2006

Related U.S. Application Data
(62) Division of application No. 10/740,469, filed on Dec. 22, 2003.

(30) Foreign Application Priority Data
Dec. 24, 2002 (JP) 2002-371818
Jun. 19, 2003 (JP) 2003-174298

(51) Int. Cl. H05K 3/30; H05K 3/34

(52) U.S. Cl. 361/775; 29/840; 29/834; 361/704; 228/180.21

(57) ABSTRACT

A control circuit board has an end portion formed with a cut that is opened sideways. The cut is coated with a conductor layer. Upon connecting the control circuit board to a conductor such as a bus bar, solder is supplied so as to bridge the conductor layer and the bus bar in a state that the conductor layer is laid on the bus bar.

### CROSS-REFERENCE TO RELATED APPLICATIONS

This is a Divisional of application Ser. No. 10/740,469, filed Dec. 22, 2003, which claims benefit of Japanese Patent Application Nos. 2002-371818, filed Dec. 24, 2002 and Japanese Patent Application No. 2003-174298, filed Jun. 19, 2003; the entire disclosures of which are hereby incorporated by reference in their entirety.

### BACKGROUND

The present invention relates to a technique for connecting a control circuit board incorporating a control circuit to an external circuit that is formed by bus bars, etc.

An electric connection box in which fuses and relay switches are incorporated in a power distribution circuit that is formed by laminating a plurality of bus bar boards is known as a means for distributing electric power to electronic units from a common vehicle power source.

For example, JP-A-10-35375 discloses an electric connection box that is provided with a bus bar board forming a current circuit, FETs as switching elements incorporated in the current circuit, and a control circuit board for controlling the operations of the FETs. The bus bar board and the control circuit board are arranged in the vertical direction so as to be separated from each other and the FETs are provided in between. The drain terminals and the source terminals of the FETs are connected to the bus bar board and their gate terminals are connected to the control circuit board.

The electric connection box disclosed in the above publication requires at least two boards (the bus bar board and the control circuit board). Further, it is necessary that the these boards be arranged three-dimensionally so as to be separated from each other and that a space for accommodating elements such as the FETs be provided between the two boards. Therefore, the total configuration is complex and sufficient miniaturization cannot be attained. In particular, the reduction of the height dimension is an important issue.

An exemplary means that is effective in solving the above problems is such that the control circuit board and bus bars constituting a power circuit are directly laid on each other and electrically connected to each other at proper locations. An exemplary means for the above electrical connections is such that through-holes are formed through the control circuit board and the control circuit board is connected to the bus bars by supplying solder to the through-holes. However, in these connection structures, it is difficult to check visually and externally whether the soldering in the through-holes is proper. This is a factor that is disadvantageous in terms of the quality management.

### SUMMARY

The invention provides, as a means for solving the above problems, a control circuit board comprising: a connecting portion to be connected to an external circuit, wherein the connecting portion is configured such that an end portion of the control circuit board is formed with a cut which is opened sideways and is coated with a conductor layer in such a manner that an inner side surface of the cut is covered with the conductor layer, the conductor layer is connected to a circuit that is incorporated in the control circuit board.

With this configuration, a conductor portion (e.g., bus bar) of an external circuit can be electrically connected to a control circuit of the control circuit board by performing soldering in such a manner that solder is supplied so as to bridge the inner circumferential surface of the conductor layer and a surface of the particular bus bar in a state that a coating portion of the conductor layer is laid on the conductor portion. This connection method makes it more easier to check visually and externally whether the soldering has been done properly at the connection position and to thereby secure higher reliability of connection than, for example, with a structure that the control circuit board is formed with a through-hole and solder is supplied to it.

The invention also provides a circuit structural body using the above control circuit board, wherein a plurality of bus bars that are part of a power circuit are bonded to a surface of the control circuit board in a state that the bus bars are arranged approximately in the same plane, and wherein a particular one of the bus bars is electrically connected to the circuit incorporated in the control circuit board by soldering in which solder is supplied so as to bridge an inner circumferential surface of the conductor layer of the control circuit board and a surface of the particular bus bar in a state that a coating portion of the conductor layer is laid on the particular bus bar.

With this configuration, since the plurality of bus bars that are part of the power circuit are bonded to the surface of the control circuit board in a state that the bus bars are arranged approximately in the same plane, the height (i.e., thickness) dimension of the entire circuit structural body is very small. Further, basically, a bus bar board (bus bars are held by an insulative board) that is necessary in a conventional electric connection box is no longer necessary. Therefore, the entire structure is made much thinner and simpler than in the conventional electric connection box in which the bus bar board and the control circuit board are separated from each other.

The circuit structural body may be such that a switching element is provided in the power circuit including the bus bars, the control circuit board incorporates a control circuit for controlling driving of the switching element, and the switching element is mounted so as to bridge the bus bar and the control circuit board. This configuration further decreases the height (i.e., thickness) dimension of the entire circuit structural body and hence the entire structure is made even thinner and simpler.

In the above circuit structural body, the particular bus bar(s) to which the conductor layer of the control circuit board is connected may be selected arbitrarily. For example, a plurality of bus bars may project sideways from the control circuit board to serve as terminals to be connected to an external circuit. This facilitates the connection between the power circuit including the bus bars and the external circuit. At least part of the bus bars to serve as the terminals may be electrically connected to the conductor layers by soldering.

More specifically, the terminals to which the conductor layers are connected by soldering may include, for example, signal input terminals to which instruction signals are input externally. In this case, a simple configuration obtained merely by electrically connecting bus bars to serve as the signal input terminals to the control circuit provided in the control circuit board makes it possible to input prescribed instruction signals to the control circuit board.

### BRIEF DESCRIPTION OF THE DRAWINGS

FIG. 1 is a perspective view of a bus bar structural plate and a control circuit board that are used in a manufacturing method of a circuit structural body according to an embodiment of the present invention;

FIG. 2 is a perspective view showing a state that the bus bar structural plate and the control circuit board are bonded to each other;

FIG. 3 is a perspective view showing a state that FETs are mounted on the bus bar structural plate and the control circuit board;

FIG. 4 is an enlarged perspective/sectional view showing how an FET is mounted;

FIG. 5 is a perspective view showing positions where the bus bar structural plate and the control circuit board are connected to each other directly;

FIG. 6 is a perspective view showing a state that the end portions of prescribed bus bars of the bus bar structural plate are bent upward;

FIG. 7 is a perspective view showing a state that a housing is provided around the end portions of signal input terminal bus bars that are bent, whereby a connector is formed;

FIG. 8 is a perspective view showing a state that bus bars are cut away from each other and an outer frame is removed from the bus bar structural plate;

FIG. 9 is a perspective view showing a state that a case is attached to the control circuit board and the bus bars;

FIG. 10 is a perspective view of the circuit structural body to which the case is attached and a heat radiation member to be attached to the circuit structural body;

FIG. 11 is a perspective view of the circuit structural body to which the heat radiation member is attached and a cover to be attached to a water protection wall of the case of the circuit structural body;

FIG. 12 is a perspective view showing a state that the cover is attached;

FIG. 13(a) is a bottom view of a control circuit board showing an example in which a through-hole structure is employed to electrically connecting a signal input terminal bus bar to the control circuit board, and FIG. 13(b) is a front sectional view thereof;

FIG. 14(a) is a plan view showing a soldering structure according to the invention, and FIG. 14(b) is a front sectional view thereof; and

FIG. 15 is a perspective view as viewed from above of the soldering structure of FIG. 14.

### DETAILED DESCRIPTION OF EMBODIMENTS

A preferred embodiment of the present invention will be hereinafter described with reference to the drawings. This embodiment is directed to an exemplary use of a control circuit board according to the invention, more specifically, a manufacturing method of a circuit structural body as a power distribution circuit for distributing electric power from a common power source mounted on a vehicle or the like to a plurality of electric loads. However, the uses of control circuit boards according to the invention are not limited to it and the invention can be applied broadly to cases that a control circuit board according to the invention is electrically connected to an external circuit.
1) Bus Bar Forming Step

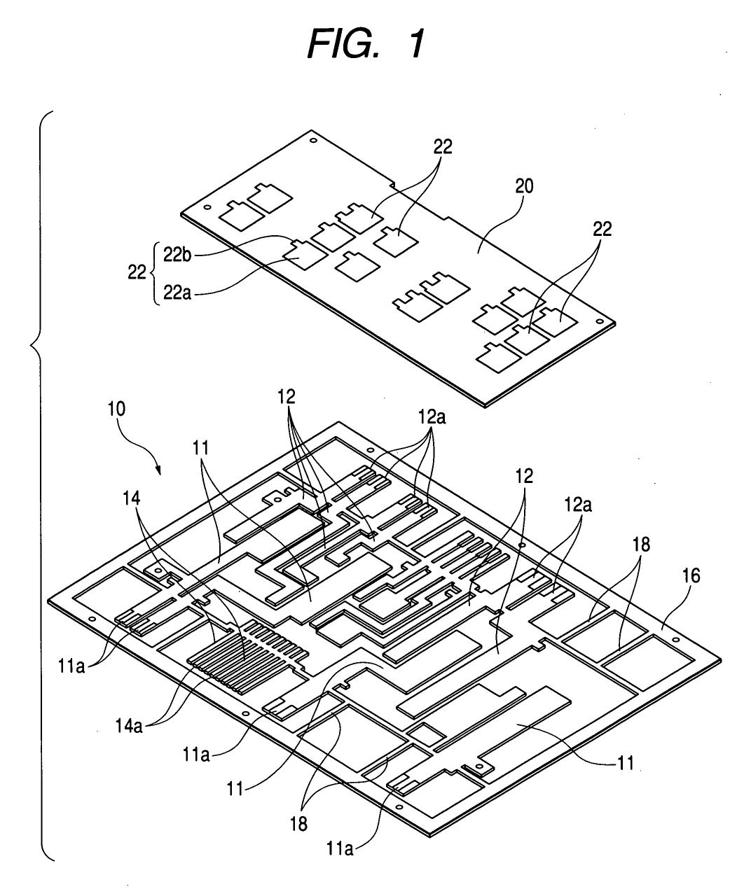

First, to manufacture a circuit structural body, a bus bar structural plate 10 is formed as shown in FIG. 1.

The illustrated bus bar structural plate 10 has a rectangular outer frame 16. A large number of bus bars including plurality of input terminal bus bars 11 as input terminals, a plurality of output terminal bus bars 12 as output terminals, and a plurality of signal input terminal bus bars 14 and having prescribed patterns are arranged inside the outer frame 16. Proper bus bars are connected to the outer frame 16 by small-width joints 18, and particular bus bars are connected to each other by small-width joints 18.

In the illustrated example, all of end portions 11a of the input terminal bus bars 11 and outside ends 14a of the signal input terminal bus bars 14 are arranged along the left sideline of the bus bar structural plate 10 and all of end portions 12a of the output terminal bus bars 12 are arranged along the right sideline of bus bar structural plate 10. The bus bar end portions 11a, 12a, and 14a are free end portions that are not connected to the outer frame 16.

For example, the bus bar structural plate 10 can easily formed by punching a single metal plate by press working.

The outer frame 16 need not always be included. However, the inclusion of the outer frame 16 increases the rigidity of the entire bus bar structural plate 10 and thereby facilitates the work of bonding it to a control circuit board 20. Further, gripping the outer frame 16 makes it possible to handle the bus bar structural plate 10 easily without damaging the bus bar themselves. In addition, after bonding, a proper power circuit can easily be obtained by cutting the outer frame 16 away the bus bar portion.
2) Bonding Step

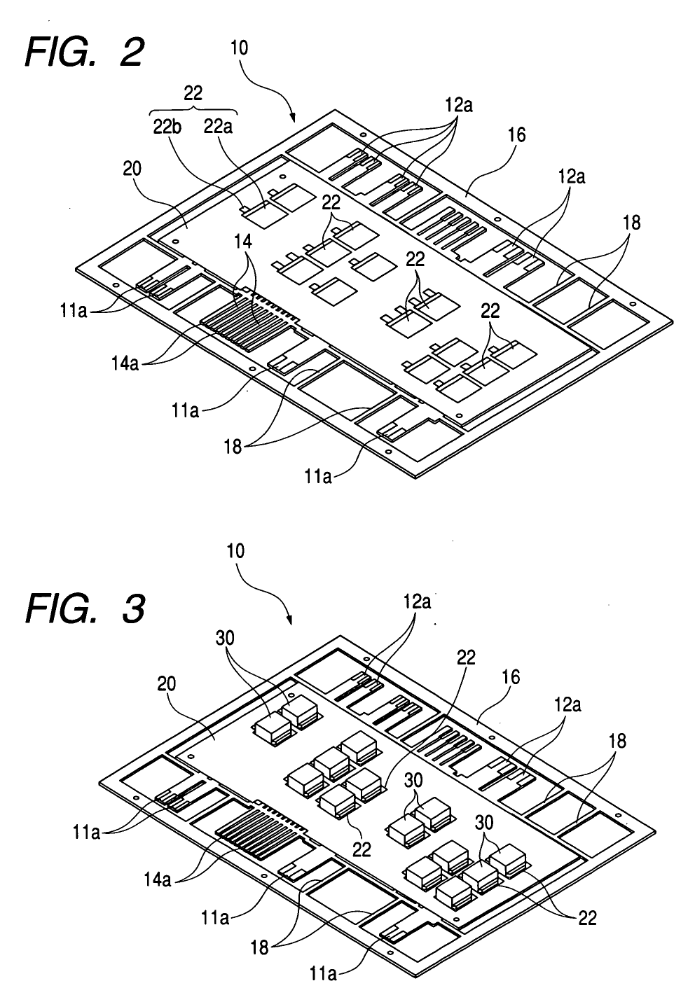

The control circuit board 20 is bonded to one surface (in FIG. 1, the top surface) of the bus bar structural plate 10 to establish a state of FIG. 2.

The control circuit board 20 includes a control circuit for controlling the switching operations of FETs (switching elements; described later) 30 and can be an ordinary printed circuit board (conductors as part of the control circuit are print-wired on an insulative board), for example. In the illustrated example, to enhance the reduction of the total thickness and the improvement in waterproofness, the control circuit board 20 is very thin (e.g., 0.3 mm) and assumes a sheet-like form. Through-holes 22 are formed through the control circuit board 20 at proper positions. The through-holes 22 are to allow mounting of the FETs 30 on the bus bars and will be described later in detail.

In this invention, there are no specific limitations on the size and shape of the control circuit board 20. In the illustrated example, the outward size of the control circuit board 20 is smaller than that of the bus bar structural plate 10; in particular, the right-left width of the former is much smaller than that of the latter. More specifically, the control circuit board 20 is bonded to a central portion of the bus bar structural plate 10 as shown in FIG. 2, whereby the end portions 11a of the input terminal bus bars 11 and the end portions 14a of the signal input terminal bus bars 14 project leftward from the control circuit board 20 and the end portions 12a of the output terminal bus bars 12 project rightward from the control circuit board 20. And all the joints 18 are located outside the control circuit board 20 and hence are exposed (see FIG. 2).

Various methods can be used to bond the control circuit board 20 to the bus bar structural plate 10. Examples of those methods will be described below.

(1) Conductor patterns are formed on both of the front and back surfaces of the control circuit board 20. Adhesive is applied to the back side (in FIG. 1, bottom side) patterns or the bus bar structural plate 10 and the back side patterns are bonded to the top surfaces of the bus bars. In this case, only patterns that should be given the same potentials as the bus bars are formed on the back surface of the control circuit board 20.

(2) Insulative adhesive is applied to the back surface of the control circuit board 20 or the top surface of the bus bar structural plate 10 so as to serve as an insulating layer between the control circuit board 20 and the bus bars. Where the control circuit board 20 includes through-holes or cuts according to the invention, the insulative adhesive is prevented from being applied to those portions (described later in detail).

(3) Adhesive is applied to only a peripheral portion of the back surface of the control circuit board 20 and the peripheral portion is bonded to the top surfaces of the bus bars. In this case, the bonding region corresponds to only the peripheral portion and the control circuit board 20 and the bus bars are free from each other: the stress is reduced accordingly.

In each of the cases (1)-(3), the adhesive can be applied by printing, which can increase the efficiency of the manufacturing process and promote its automatization.
3) Mounting Step

The FETs 30 as switching elements are mounted on both of the control circuit board 20 and the bus bar structural plate 10 by using the through-holes 22 of the control circuit board 20.

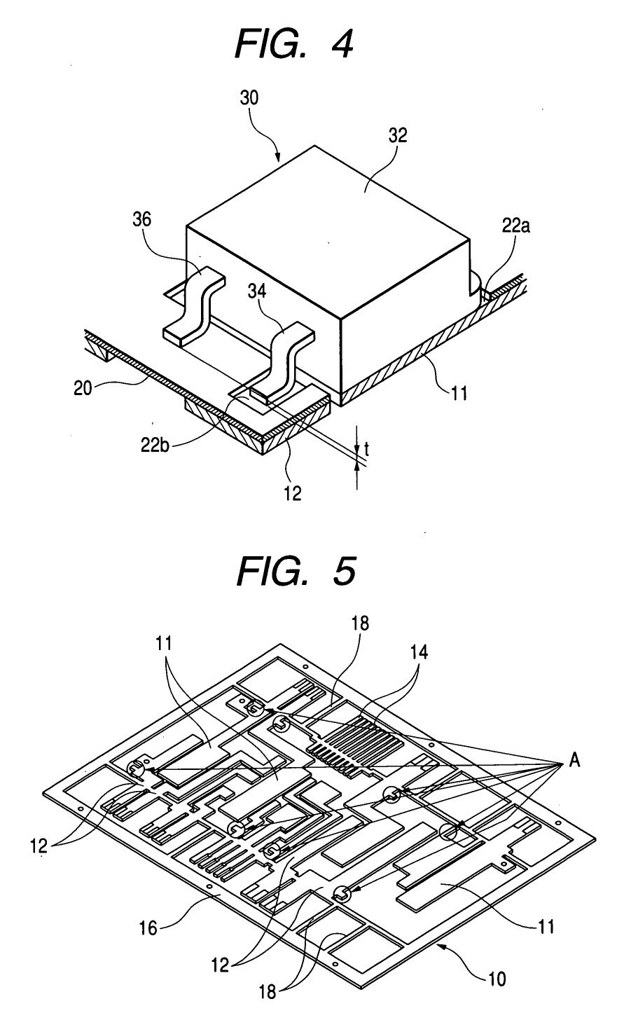

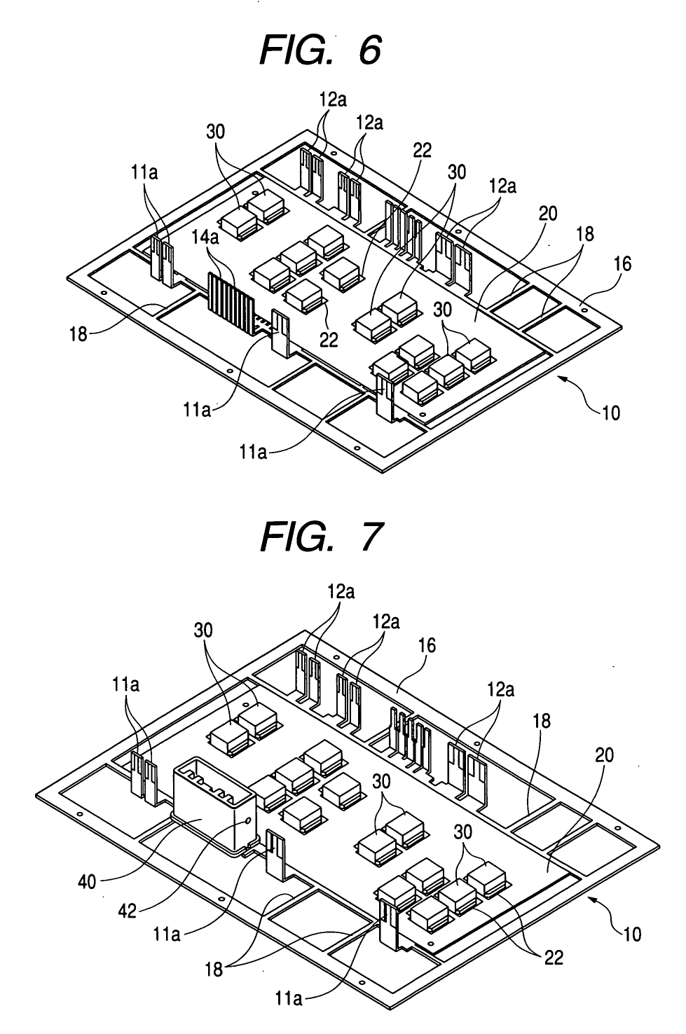

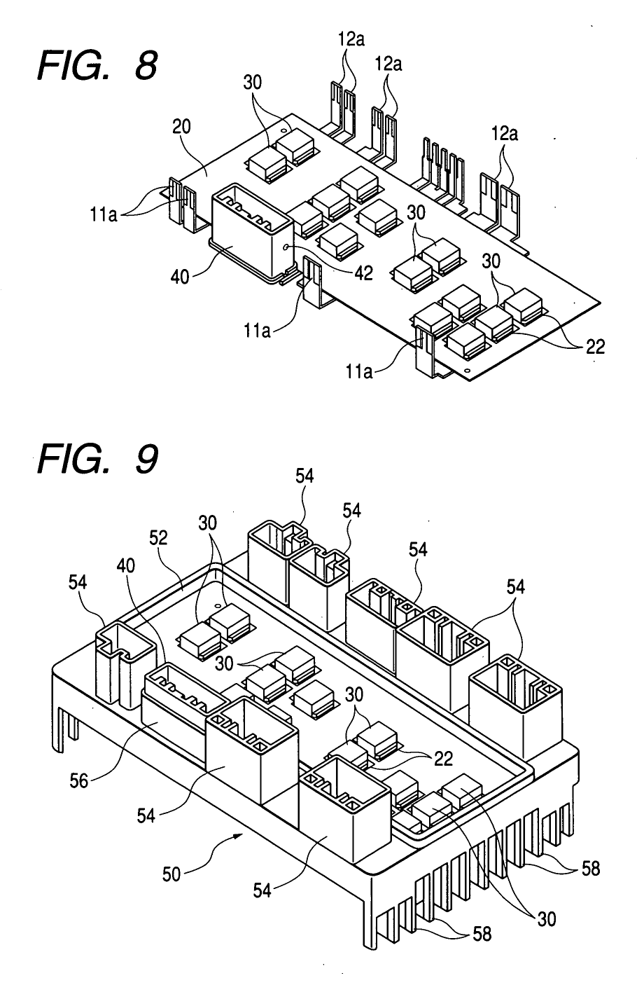

As shown in FIG. 4, each FET used has a generally rectangular-parallelepiped-shaped main body 32 and at least three terminals (a drain terminal (not shown), a source terminal 34, and a gate terminal 36). Among those terminals, the drain terminal is formed on the back surface of the main body 32 and the source terminal 34 and the gate terminal 36 project from a side surface of the main body 32 and extend downward.

So as to conform to the associated FET 30, each through-hole 22 of the control circuit board 20 has a rectangular portion 22a through which the main body 32 of the FET 30 can be inserted and an extension 22b that extends from the rectangular portion 22a in a prescribed direction and is shaped so that the source terminal 34 of the FET 30 can be inserted through it. The drain terminal formed on the back surface of the FET main body 32 is brought, through the rectangular portion 22a, into direct contact with the top surface of the associated input terminal bus bar 11 of the bus bar structural plate 10 and the FET main body 32 is mounted on the bus bar 11. The source terminal 34 of the FET 30 is connected to the associated output terminal bus bar 12 through the extension 22b, and the gate terminal 36 of the FET 30 is connected to a proper conductor pattern of the control circuit board 20.

That is, in this mounting step, all the FETs 30 can be mounted on both of the control circuit board 20 and the bus bars from above at the same time. The efficiency of assembling work is made very much higher than in a conventional method in which FETs are separately connected to a bus bar board and a control circuit board via respective wiring means.

The mounting step can easily be executed merely by, for example, applying molten solder by printing or the like so as to be placed in the through-holes 22 and putting the FETs 30 on the solder.

To execute the mounting step, it is even preferable that as shown in FIG. 4 the source terminal 34 and the gate terminal 36 are given, in advance, a level difference t that is approximately equal to the thickness of the control circuit board 20. This makes it possible to mount the terminals 34 and 36 on the output terminal bus bar 12 and the control circuit board 20, respectively, as they are without undue deformation of the terminals 34 and 36 in spite of the fact that the control circuit board 20 has a certain thickness: the stress remaining in each terminal after the mounting can be reduced to a large extent.

The switching elements used in the invention is not limited to the FETs 30 and may be mechanical relay switches, for example. It is also possible to mount the switching elements on only the control circuit board 20 and to construct, on the control circuit board 20 side, part of a power circuit including the switching elements.
3′) Electric Connection Step

The bus bars of the bus bar structural plate 10 include ones that should be connected to the control circuit of the control circuit board 20 directly (i.e., without intervention of the FETs 30). Electrical connections for those bus bars will be described later in detail.
4) Bending Step

The end portions of the bus bars (in the figure, including the end portions 11a, 12a, and 14a of the bus bars 11, 12, and 14) projecting from the control circuit board 20 rightward or leftward are bent upward to form terminals to be connected to external circuits. The execution of the bending step makes it possible to connect external wiring members to the respective terminals from one side and to thereby simplify the connection work.
5) Housing Attaching Step (Connector Formation Step-1)

As shown in FIG. 7, a housing 40 made of an insulative material such as a synthetic resin is fixed so as to surround a plurality of signal input terminals (in the figure, the end portions 14a of the signal input terminal bus bars 14 that are arranged in line), whereby a connector is formed. A projection 42 for engagement with a case 50 (described later) is formed on a side surface of the housing 40 in advance.
6) Separation Step

The bus bars of the bus bar structural plate 10 are separated from each other by press working, whereby a power circuit is completed. More specifically, the joints 18 that are located outside the control circuit board 20 and hence are exposed are cut away. The removal of the joints 18 necessarily means removal of the outer frame 16 from the circuit structural body. After the execution of the separation step, the height (thickness) dimension of the entire structure is very small and its occupation area is approximately the same as the area of the control circuit board 20. This circuit structural body can be used solely. However, its waterproofness and heat radiation performance can be enhanced by adding a case 50 and a heat radiation member 60 (both described later), whereby a circuit body suitable for use as a vehicular power distributor, for example, can be obtained.

The separation step may be executed before the steps 3)-5). The separation step should be executed before those steps in the case where the bus bar end portions 11a, 12a, and 14a to form terminals are connected to the outer frame 16 or other bus bars.
7) Case Attaching Step (Connector Formation Step-2)

A case 50 (see FIG. 9) made of an insulative material such as a synthetic resin is applied from above to the circuit structural body obtained by the separation step of item 6). Having a bottom opening, the case 50 is shaped so as to cover the entire control circuit board 20 from above. Openings through which the FETs 30 are to project upward are formed in a central area and a water protection wall 52 erects upward from the periphery of the area of those openings. That is, the water protection wall 52 surrounds the area where the FETs 30 are to exist.

Housings 54 and a housing attachment portion 56 all of which are shaped like a pipe and have top and bottom openings are formed on right and left peripheral portions (i.e., on the right and left sides of the water protection wall 52) of the case 50 so as to be integral with the case 50. The housings 54 are formed at a plurality of positions so as to surround the end portions 11a (input terminals) of the input terminal bus bars 11 and the end portions 12a (output terminals) of the output terminal bus bars 12, respectively, and thereby constitute connectors together with those terminals. The housing attachment portion 56 is formed at the position corresponding to the housing 40 mentioned before (i.e., the housing that surrounds the signal input terminals). The housing 40 is inserted into the housing attachment portion 56 from below and the projection 42 on the side wall of the housing 40 is engaged with the top end of the housing attachment portion 56, whereby the bus bars and the control circuit board 20 are locked with the case 50.

With this structure, the terminals can easily be connected to external circuits by connecting, to connectors formed by the terminals and the housings 40 and 54, connectors that are provided at the ends of wire harnesses that are cabled in a vehicle, for example.

A plurality of fin covers 58 that are arranged in the right-left direction project downward from the front and rear end portions of the case 50.
8) Heat Radiation Member Connecting Step

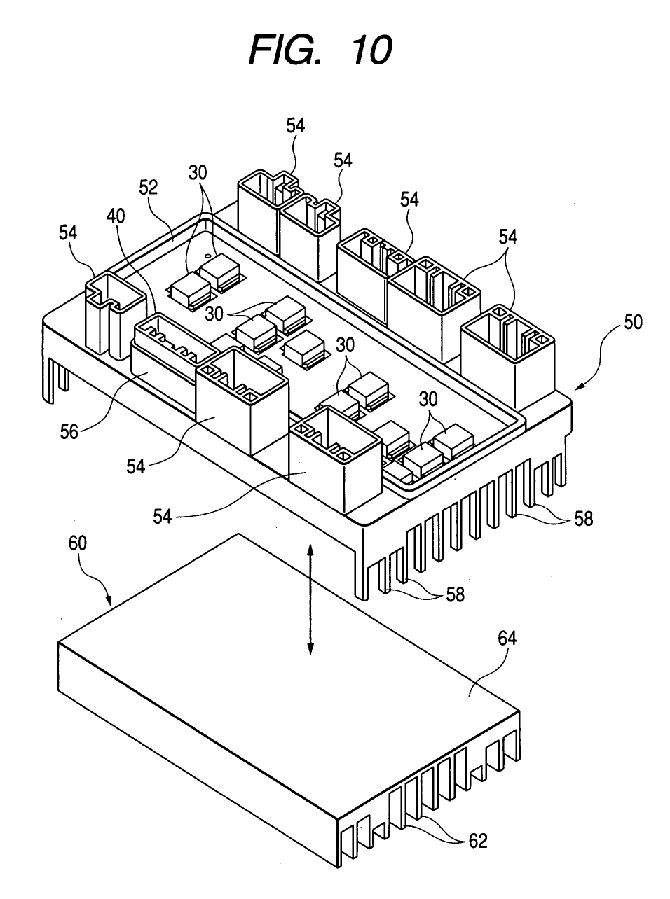

The top surface 64 of a heat radiation member 60 shown in FIG. 10 is bonded to the bottom surfaces of the bus bars, whereby the heat radiation member 60 and the bus bars are united with each other.

The heat radiation member 60 as a whole is made of a material that is superior in thermal conductivity, such as an aluminum-based metal. The heat radiation member 60 has the flat top surface 64, and a plurality of fins 62 arranged in the right-left direction project downward from the bottom surface. The positions of the fins 62 correspond to the positions of the fin covers 58 of the case 50. When the heat radiation member 60 is attached, both ends (in the longitudinal direction) of each fin 62 is covered with the associated fin covers 58.

It is preferable that the bonding of the heat radiation member 60 to the bus bars be performed according to the following exemplary procedure:

(1) An epoxy resin as an insulative adhesive is applied to the top surface 64 of the heat radiation member 60 and then dried, whereby a thin-film insulating layer is formed.

(2) An adhesive (e.g., grease-like one such as a silicone adhesive) that is softer and higher in thermal conductivity than the material of the above insulating layer is applied to (laid on) the insulating layer or the bus bars, and the bus bars are bonded to the heat radiation member 60 with the adhesive.

The insulating layer of item (1) is not always necessary. However, the formation of the insulating layer makes it possible to secure electrical insulation reliably while minimizing the amount of use of the adhesive of item (2) (i.e., the adhesive that is soft and superior in thermal conductivity) which is expensive. Alternatively, it is possible to form the insulating layer of item (1) by, for example, sticking an insulating sheet to the top surface 64 of the heat radiation member 60.

Where the bus bars include ones that should be grounded, the heat radiation member 60 may be grounded by fixing the heat radiation member 60 to those bus bars by screwing.

It is preferable that the heat radiation member 60 be fixed to the case 50 by providing an engagement portion that is engaged with the case 50 and the heat radiation member 60 in addition of the bonding of the heat radiation member 60 to the bus bard. The waterproofness of the circuit structural body can further be enhanced by interposing a sealing member made of silicone rubber or the like between the case 50 and the heat radiation member 60.
9) Potting Step

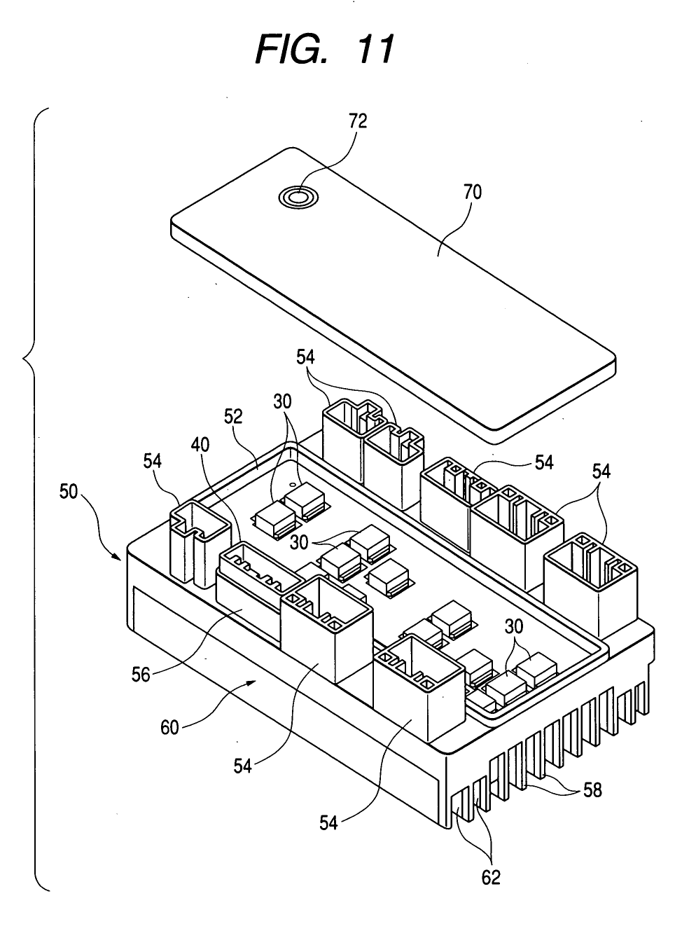

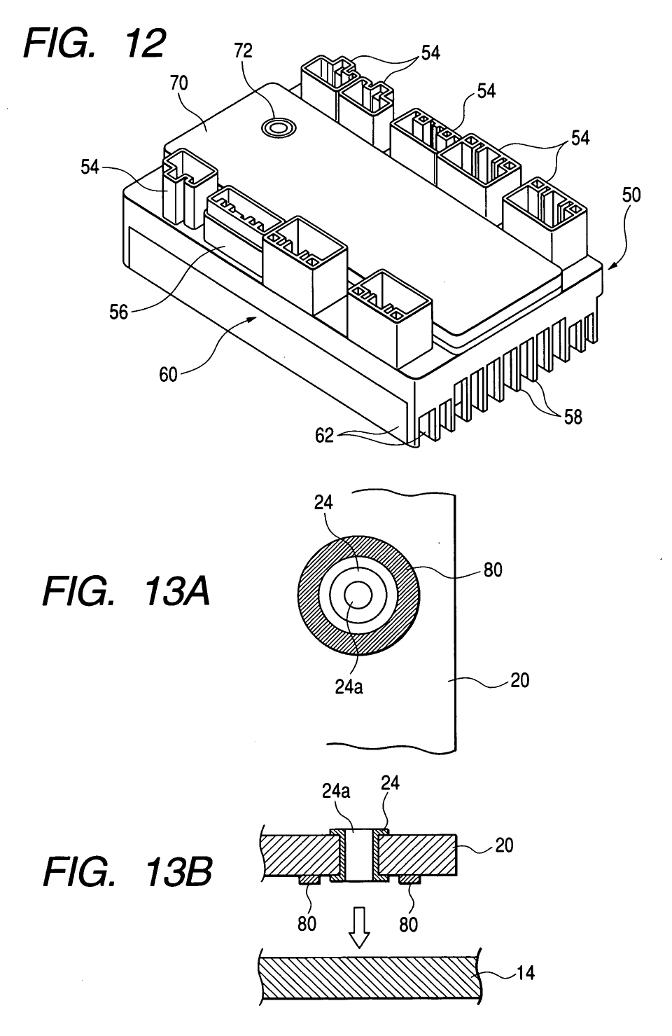

A potting agent for heat radiation promotion is injected into the inside space of the water protection wall 52. Then, a cover 70 shown in FIG. 11 is placed on the top end of the water protection wall 52 and they are bonded to each other (by vibration welding, for example), whereby the inside space of the water protection wall 52 is confined tightly and protected from water.

Power sources are connected to the input terminals (i.e., the end portions 11a of the input terminal bus bars 11) of the thus-manufactured circuit structural body and proper electric loads are connected to its output terminals (i.e., the end portions 12a of the output terminal bus bars 12), whereby a power distribution circuit for distributing electric power to the electric loads from the power sources is constructed. Further, the operations of the FETs 30 provided in the power distribution circuit are controlled by the control circuit that is incorporated in the control circuit board 20, whereby the energization on/off control on the power distribution circuit is performed.

Next, the above-mentioned electric connection step will be described. That is, a structure and a method for directly connecting part of the bus bars to the control circuit board 20 (i.e., electrical connections without intervention of the FETs 30) will be described.

A means for such connections that would be conceived first is as follows. For example, a cylindrical land (conductor layer) 24 shown in FIGS. 13(a) and 13(b) is caused to penetrate through the board body of the control circuit board 20. Adhesive 80 is applied so as to surround the land 24. After the surface of a particular bus bar (in the figure, a signal input terminal bus bar 14 to serve as a signal input terminal) is bonded to the control circuit board 20 with the adhesive 80, solder is supplied to the inside space of a through-hole 24a of the land 24 to as to bridge the inner circumferential surface of the land 24 and the surface of the signal input terminal bus bar 14. However, this method has a drawback that it is very difficult to visually check whether the soldering has been done properly in the through-hole 24a.

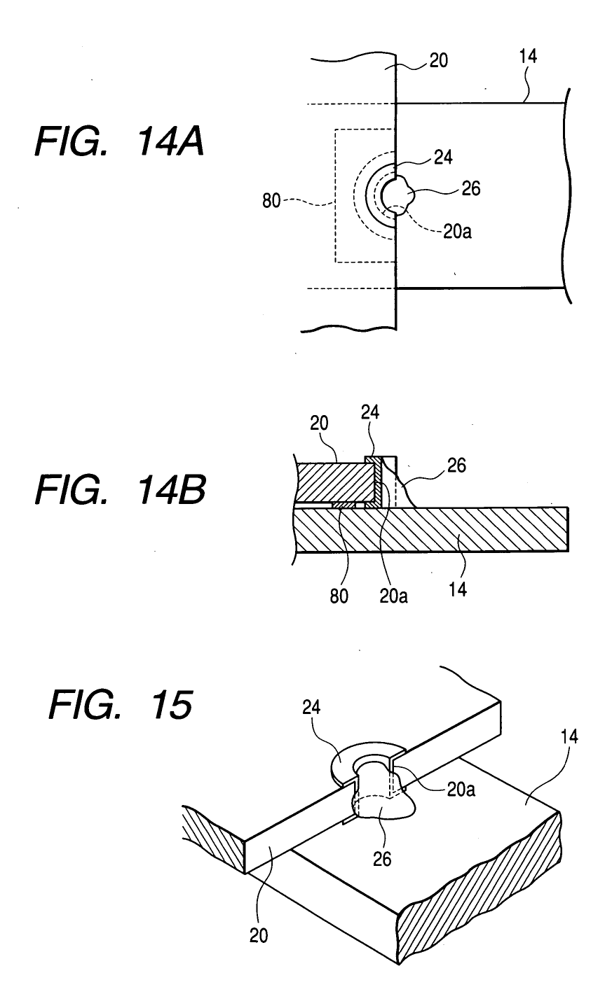

In contrast, the invention employs a structure shown in FIGS. 14(a), 14(b), and 15. As shown in the figures, an end face of the control circuit board 20 is formed with a semi-circular cut 20a and that portion of the control circuit board 20 is coated with a generally semi-cylindrical land (conductor layer) 24 in such a manner that the surface of the cut 20a is covered with the land 24. The land 24 is electrically connected to a conductor pattern (i.e., a pattern that is part of the control circuit) that is printed on the control circuit board 20. Adhesive 80 is applied to the back surface of the control circuit board 20 so as to surround the land 24. A signal input terminal bus bar 14 is bonded to a peripheral portion of the control circuit board 20 with the adhesive 80. Solder is supplied so as to bridge the semi-cylindrical inner circumferential surface of the land 24 and the surface of the input terminal bus bar 14 (in the figures, a solder fillet 26 is formed), whereby the signal input terminal bus bar 14 is electrically connected to the land 24.

For example, this connection is made according to the following procedure:

(1) Before execution of a bonding step, an end face of the control circuit board 20 is formed with a cut 20a that is opened sideways and that portion of the control circuit board 20 is coated with a land 24 in such a manner that the inner side surface of the cut 20a is covered with the land 24. In this state, the land 24 is connected to a conductor pattern that is printed on the control circuit board 20 (conductor layer coating step).

(2) Adhesive 80 is applied to the back surface of the control circuit board 20 so as to surround the land 24, and a signal input terminal bus bar 14 is bonded to the control circuit board 20 with the adhesive 80 (bonding step). As a result of the bonding, the back face of the land 24 is kept laid on the signal input terminal bus bar 14.

(3) In the state of item 2), solder is supplied so as to bridge the inner circumferential surface of the land 24 and the surface of the input terminal bus bar 14, whereby a fillet 26 is formed as shown in the figures.

According to the above structure and method, the fillet 26 that is finally formed is exposed sideways. Therefore, it is possible to check externally at a glance whether the soldering has been done properly, which makes it possible to secure stable quality and high reliability of connection.

In the invention, the structure of FIGS. 14(a), 14(b) and 15 need not always be employed at every connecting position between the control circuit board and bus bars. The through-hole connecting structure of FIGS. 13(a) and 13(b) or some other structure may be employed at part of the connecting positions. For example, a structure in which a bus bar is formed with a proper projection (indicated by character A in FIG. 5) and the projection is soldered to the control circuit board 20 and the structure of FIGS. 14(a), 14(b) and 15 may be used jointly.

The bus bars that are directly connected to the control circuit board 20 are not limited to signal input terminal bus bars. For example, the invention can also be applied to a case that output bus bars 12 to be used for inputting output current information to the control circuit board 20 are directly connected to the control circuit board 20.

Further, the subjects to be connected to the control circuit board 20 are not limited to bus bars (the above-described case). For example, the invention can also be applied to a case that a thick copper foil board, a copper-plate-stuck board, or the like for large current conduction or a connector or the like is connected to the control circuit board 20.

There are no specific limitations on the shapes of the cut 20a and the land (conductor layer) 24 with which the cut 20a is covered. In addition to the semi-cylindrical shape shown in the figures, shapes that are opened sideways such as a horseshoe shape, a bracket shape, and a V-shape (all as viewed in a plan view) may be used.

As described above, according to the invention, an end portion of a control circuit board is formed with a cut that is opened sideways and the control circuit board is coated with a conductor layer in such a manner that the inner side surface of the cut is covered with the conductor layer, whereby the conductor layer is connected to a circuit that is incorporated in the control circuit board. Therefore, a connection subject such as a bus bar (i.e., particular bus bar) can be electrically connected to the circuit incorporated in the control circuit board by performing soldering in such a manner that solder is supplied so as to bridge the inner circumferential surface of the conductor layer and a surface of the particular bus bar in a state that a coating portion of the conductor layer is laid on the particular bus bar. Further, whether the soldering has been done properly can easily be checked visually and externally, which provides an advantage that the quality is made stable and the reliability of connection is increased.

What is claimed is:

1. A method for connecting a control circuit board to an external circuit in which the control circuit board is electrically connected to conductors that are part of the external circuit, the control circuit board including a connecting portion to be connected to the external circuit, the connecting portion is configured such that an end portion of the control circuit board is formed with a cut which is opened sideways and is coated with a conductor layer in such a manner that an inner side surface of the cut is covered with the conductor layer, the conductor layer is connected to a circuit that is incorporated in the control circuit board, the method comprising:
laying the conductor and a coating portion of the conductor layer one on another; and
soldering in which solder is supplied so as to bridge the inner circumferential surface of the conductor layer and a surface of the conductor in a state that the conductor and the coating portion of the conductor layer are laid one on another.
